(19) United States
(12) Patent Application Publication
(10) Pub. No.: US 2010/0089177 A1
(43) Pub. Date: Apr. 15, 2010

(54) TENSIONER SENSOR (BTS)

(76) Inventors: Daryn L. Waite, Arlington Heights, IL (US); David L. Maloney, Barrington, IL (US)

Correspondence Address: Brinks Hofer Gilson & Lione/Ann Arbor, 524 South Main Street, Suite 200, Ann Arbor, MI, 48104, US

(21) Appl. No.: 12/515,147

(22) PCT Filed: Nov. 30, 2007
(86) PCT No.: PCT/US07/86115

§ 371 Date: Dec. 8, 2009

Related U.S. Application Data
(60) Provisional application No. 60/872,056, filed on Nov. 30, 2006.

(51) Int. Cl. G01L 5/04; H01L 43/06

(52) U.S. Cl. 73/862.391; 324/207.2

(57) ABSTRACT

In at least one embodiment of the present invention, a sensor assembly for measuring tension loads by a seat belt for a vehicle is provided. The assembly comprises an anchor plate forming a first aperture for mounting. The anchor plate has a central space. A housing is positioned to envelope the anchor plate and forms a seat belt aperture. The housing has a first sensor element. Engaging the seat belt aperture is the seat belt. A compliant element causes the housing to move relative to the anchor plate in response to tension by the seat belt. Within the central space is a strain relief element having positioning features to locate the strain relief element relative to the anchor plate. The strain relief element has a second sensor element interacting with the first sensor element to produce a signal responsive to the relative position between the housing and the anchor plate.

### CROSS REFERENCE TO RELATED APPLICATIONS

This application claims the benefit of Provisional Application Number 60/872,056, filed Nov. 30, 2006, and PCT/US2007/086115, filed Nov. 30, 2007, the contents of which are incorporated herein by reference thereto.

### BACKGROUND OF THE INVENTION

1. Field of the Invention

The present invention relates generally to seat belt restraint systems for vehicles and, more particularly, to a belt tension sensor (BTS) assembly for a seat belt restraint system in a vehicle.

2. Background

Seat belt restraint systems, for restraining an occupant in a vehicle seat play an important role in vehicle crash situations. Seat restraint systems typically have a lap belt and a shoulder belt. Typically, the lap belt and the shoulder belt are connected together at one end. A seat restraint system includes a latch plate at the connected end. The seat restraint system also includes a buckle connected at one end by webbing or the like to the vehicle structure. The buckle receives the latch plate to be buckled together. When the buckle and the latch plate are buckled together, the seat restraint system restrains movement of the occupant during a collision.

Vehicle manufactures often incorporate systems particularly used with inflatable restraint systems to determine if an occupant is in a seat of the vehicle. Decisions on deployment of inflatable restraints may depend on information supplied by sensors in the seat in determining an occupant's weight or type of object in the seat. When a child seat is placed in the seat and tightly secured in place by the seat restraint system, the seat sensors may read a large mass instead of a child seat. In this scenario, however, there will be high tension in the seat restraint system. Comfort studies have shown that adult occupants do not wear their seat belt or seat restraint system that tight. It is undesirable to deploy an inflatable restraint system for a seat with a child restraint system in place. Thus, information regarding the seat restraint tension is important in determining whether the inflatable restraint system should deploy an inflatable restraint.

Accordingly, it is desirable to provide an assembly for sensing tension in a seat restraint system of a vehicle. Moreover, it is desirable that such an assembly for sensing tension is reliable and robust.

### BRIEF SUMMARY OF THE INVENTION

Embodiments of the present invention provide a sensor assembly for measuring tension loads applied by a seat belt for a motor vehicle that may have enhanced reliability and robustness. More specifically, the sensing system of the present invention provides non-contact sensor elements arranged in a manner with other components of the assembly to avoid being directly strained or stressed while detecting tension forces imparted by the seat belt. By minimizing and/or relieving the strain within the assembly, fatigue and/or wear issues, which may otherwise result, for example, from repeated tensioning and/or buckling and unbuckling of the seat belt, may be avoided. Moreover, such an arrangement may further allow for protective encapsulation of at least one of the sensor elements with connecting components of the assembly, providing better resistance to the environment, and further enhancing reliability and robustness of the assembly.

In at least one embodiment of the present invention, a sensor assembly for measuring tension loads applied by a seat belt for a motor vehicle is provided. The sensor assembly comprises an anchor plate forming a first aperture to enable the anchor plate to be mounted to the motor vehicle. The anchor plate forms a second aperture having a central space. A first edge of the anchor plate defines the central space. A housing is positioned to envelope at least a portion of the anchor plate and forms a seat belt aperture. The housing has a first sensor element. Engaging the seat belt aperture is the seat belt. A compliant element acts on the anchor plate and the housing, causing the housing to move relative to the anchor plate in response to tension loads exerted by the seat belt. Disposed within the central space of the anchor plate and between opposing sides of the first edge is a strain relief element. The strain relief element has one or more positioning features to locate the strain relief element relative to the anchor plate. The strain relief element has a second sensor element interacting with the first sensor element to produce an electrical signal responsive to the relative position between the housing and the anchor plate.

In at least one other embodiment of the present invention, the seat belt loop and the seat belt aperture of the assembly are superimposed such that the seat belt loop receives the seat belt. Tension force on a seat belt webbing causes the relative position between the housing and the anchor plate to change to a predetermined level of tension. Beyond the predetermined level of tension, tension force on the seat belt webbing is at least partially transferred to at least one of the first edge and the second edge of the anchor plate.

Further objects, features and advantages of the invention will become apparent from consideration of the following description and the appended claims when taken in connection with the accompanying drawings.

### BRIEF DESCRIPTION OF THE DRAWINGS

FIG. 1 is a perspective view of a BTS assembly for a seat restraint system in a vehicle in accordance with an embodiment of the present invention;

FIG. 2 is a perspective view of a BTS assembly for a seat restraint system in a vehicle in accordance with another embodiment of the present invention;

FIG. 3 is an exploded view of the BTS assembly depicted in FIG. 2;

FIG. 4 is a perspective view of an anchor plate component of the BTS assembly in accordance with an embodiment of the present invention;

FIG. 5 is a partial perspective view of a BTS assembly for a seat restraint system in a vehicle in accordance with yet another embodiment of the present invention;

FIG. 6 is a partial perspective view of a cross section of a BTS assembly for a seat restraint system in a vehicle in a low tension condition in accordance with another embodiment of the present invention;

FIG. 7 is a partial perspective view of a cross section of the BTS assembly depicted in FIG. 6 in a high tension condition;

FIG. 8 is a partial perspective view of a BTS assembly for a seat restraint system in a vehicle in accordance with yet another embodiment of the present invention;

FIG. 9 is an expanded perspective view of the BTS assembly for a seat restraint system in a vehicle in accordance with another embodiment of the present invention; and

FIG. 10 is another expanded perspective view of the BTS assembly depicted in FIG. 9.

### DETAILED DESCRIPTION OF THE INVENTION

Detailed embodiments of the present invention are disclosed herein. It is understood however, that the disclosed embodiments are merely exemplary of the invention and may be embodied in various and alternative forms. The figures are not necessarily to scale; some figures may be configured to show the details of a particular component. Therefore, specific structural and functional details disclosed herein are not interpreted as limiting but merely as a representative basis with the claims and for teaching one skilled in the art to practice the present invention.

Examples of the present invention seek to overcome some of the concerns associated with a sensor assembly that provides information regarding a seat occupant of a vehicle, for example, to a smart inflatable restraint system. These concerns include improving the reliability and robustness of the sensor assembly.

Employing the principles of the present invention is a sensor assembly for measuring tension loads applied by a seat belt for a motor vehicle. The sensor assembly has non-contacting sensor elements that are responsive to tension loads applied by the seat belt. At least one of the sensor elements may be electrically coupled to electrical conductors. The electrical conductors, for example, may be for communicating an electrical signal from the sensor element to a controller in response to the seat belt tension loads. The sensor assembly is configured such that the sensor elements and the electrical conductors avoid being strained or stressed while detecting tension forces imparted by the seat belt. More specifically, the sensor assembly includes a strain relief element that provides positioning and support for at least one of the sensor elements as well as positioning and support for the electrical conductors coupled to the sensor element or elements.

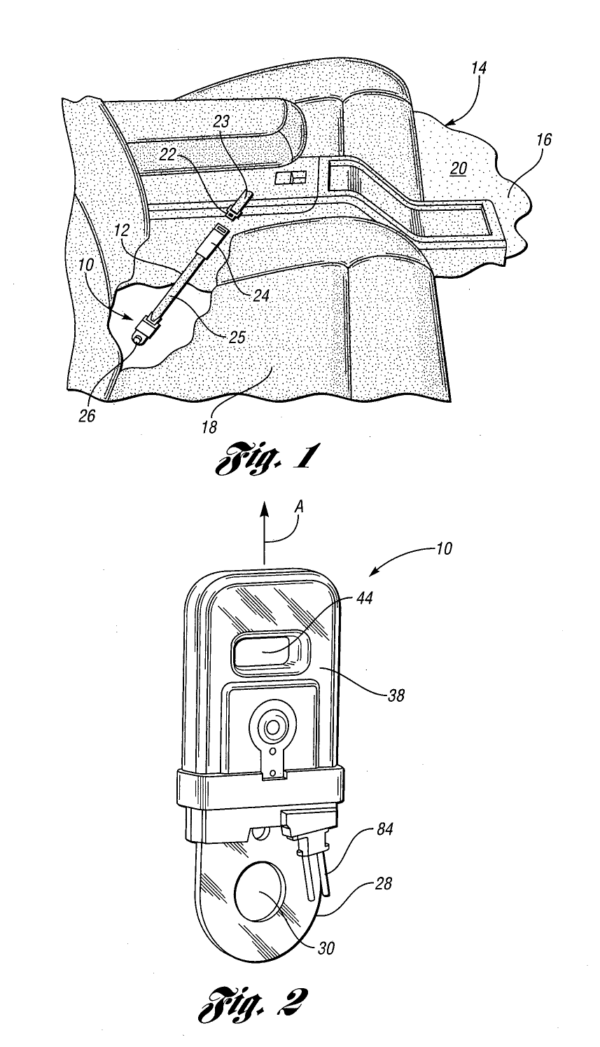

Referring now to the drawings, FIG. 1 illustrates at least one embodiment of a sensor assembly 10 for a seat belt restraint system 12 in a vehicle 14 in accordance with the present invention. The vehicle 14 includes a vehicle body 16, a seat 18 mounted by suitable means to the vehicle structure, such as for example, a floor pan (not shown) and an occupant compartment 20 within the vehicle body 16. In this embodiment, the seat 18 is a front seat of the vehicle 14. However, it should be appreciated that the seat 18 could be a rear, second row or third row seat for the vehicle 14.

The vehicle 14 includes the seat belt restraint system 12 for restraining an occupant (not shown) in the seat 18. The seat restraint system 12 includes a latched tongue or plate 22 connected to belt webbing 23 at an end of either one of a lap belt, shoulder belt, or both which have another end connected to a retractor (not shown). The seat restraint system 12 may also include a buckle assembly 24 for receiving the latch plate 22. The buckle assembly 24 is connected by a suitable means such as by a belt webbing 25 to the sensor assembly 10. The sensor assembly 10 is connected to the vehicle structure, for example, by a bolt 26.

Referring now to FIGS. 1-3, at least one embodiment of the sensor assembly 10 is provided. The sensor assembly 10 comprises an anchor plate 28 that forms a first aperture 30 for enabling the anchor plate 28 to be mounted to the motor vehicle 14, such as for example, the seat structure. The anchor plate 28 is preferably manufactured from a low alloy steel. The first aperture 30 is for receiving a mounting fastener, such as a bolt 26, which attaches to the motor vehicle 14. The anchor plate 28 also forms a second aperture 32 having a central space 34. The central space 34 is defined by a first edge 36 of the anchor plate 28.

A housing 38 is positioned to envelope at least a portion of the anchor plate 28. The housing 38 may be made of multiple pieces or portions, such as for example, a first portion 40 and a second portion 42. The first and second portions 40 and 42 of the housing 38 may be matched an aligned such that when they are assembled, the housing 38 sandwiches the anchor plate 28. In one embodiment, the housing portions 40 and 42 have features, such as an ultrasonic weld joint, so that the portions 40 and 42 may be attached together. Alternatively, the portions 40 and 42 may be attached by an adhesive or a positive fastener 78, such as a rivet or bolt.

The housing 38 may also have bearing features or stand-offs in the housing to constrain and/or limit the housing 38 from sliding linearly along the anchor plate 28 while all other degrees of freedom are substantially removed. The housing 38 also forms a seat belt aperture 44. The seat belt 25 engages the seat belt aperture 44.

The housing 38 has a first sensor element 46. In one example, the first sensor element 46 is a permanent magnet or a pair of permanent magnets, each being positioned within the first and second portions 40 and 42 of the housing 38. The first sensor element 46 may be fastened, affixed or attached to the housing 38. Alternatively, the housing 38 may be made from injection molded plastic and the first sensor element 46 may be insert molded into the housing 38.

Referring to FIGS. 1-5, the anchor plate 28 has a seat belt loop 74 defined by a second edge 76 of the anchor plate 28. The seat belt loop 74 and the seat belt aperture 44 may be concentric or superimposed so that seat belt loop 74 receives the seat belt 25 when the seat belt 25 is placed through the seat belt aperture 44.

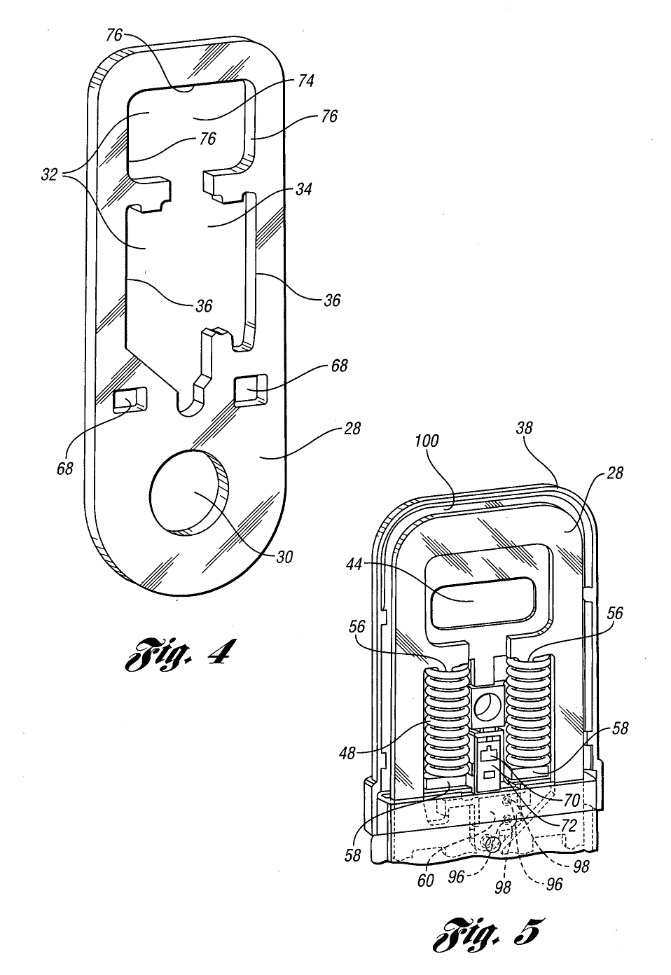

In one example illustrated in FIG. 4, the first and second edges 36 and 76 of the anchor plate 28 form the second aperture 32 and thus, the seat belt loop 74 defines a portion of the space of the second aperture 32, while the central space 34 defines another portion of the space of the second aperture 32. Alternatively and as illustrated in FIG. 3, the seat belt loop 74 may be a separate aperture, which is closed off from the second aperture 32 by the anchor plate 28.

The sensor assembly 10 further comprises a compliant element 48. The compliant element 48 may include at least one compression coil spring 50. Alternatively, the compliant element 48 may include any other suitable device known to those skilled in the art that exhibits substantially elastic or “spring like” behavior.

The compliant element 48 is disposed within the central space 34 of the second aperture 32. The compliant element 48 has a first end 52 engaging the anchor plate 28 and a second end 54 engaging the housing 38. In one example, the first end 52 engages the anchor plate 28 about a positive feature 56 and the second end 54 engages the housing 38 about a base feature 58.

In at least one embodiment, the compliant element 48 in a rest or low tension condition, biases the anchor plate 28 towards a top portion 100 of the housing 38. However, when a tension load is exerted by the seat belt 25, the compliant element 48 acts on the anchor plate 28 and the housing 38, causing the housing 38 to move relative to the anchor plate 28 such that the anchor plate 28 becomes spaced apart from the top portion 100 of the housing 38.

A strain relief element 60 is disposed within the central space 34 of the anchor plate 28 between opposing sides 62 and 64 of the first edge 36. The strain relief element 60 has one or more positioning features 66 to locate the strain relief element 60 relative to the anchor plate 28. The positioning feature 66 may be any suitable locating feature, such as for example, a post fitting into a bore 68 formed by the anchor plate 28. The post may be a positive feature, such as for example, a cylindrical or star shaped protrusion, a snap-fit feature, or any other suitable feature which may be used to locate into a bore 68. In one example, the positioning feature 66 is integrally molded into the strain relief element 60.

The bore 68 may be an opening having a circular or square shape, a slot or any other shaped opening which cooperates with the post to provide 1-way, 2-way, 3-way or 4-way location of the strain relief element 60 relative to the anchor plate 28. Moreover, the post may further cooperate with the bore 68 to attach and/or secure the strain relief element 60 to the anchor plate 28.

The strain relief element 60 has a second sensor element 70 interacting with the first sensor element 46 to produce an electrical signal responsive to the relative position between the housing 38 and the anchor plate 28. In one example, the strain relief element 60 has a first portion 120 and a second portion 122. The first portion 120 includes the positioning features 66 and is positioned on the surface of the anchor plate 28. The second portion 122 is disposed in the central space 34 and has an arm feature 124 which extends outwardly from the first portion 120 and into the central space 24. The second sensor element 70 is a Hall Effect Device (HED) which is provided on a printed circuit board (PCB) 72. The second portion 122 includes the PCB 72 with the HED positioned on the arm feature 124 such that it extends out into the central space 34. Moreover, the PCB 72 may be positioned on the second portion 122 by at least one locator positive feature 130, preferably two or more, formed by the second portion 122. The locator positive feature 130 or positive features extend through a corresponding locator opening 132 or openings formed in the PCB 72. The locator positive feature 130 may be for example, integrally mold with the strain relief element 60 or may be an inserted pin or otherwise. The PCB 72 may further be secured to the second portion 122 by deforming the locator positive feature 130 within or immediately adjacent to the locator opening 132, such as for example, by heat staking, ultrasonic welding or by any other suitable means for attaching known to those skilled in the art.

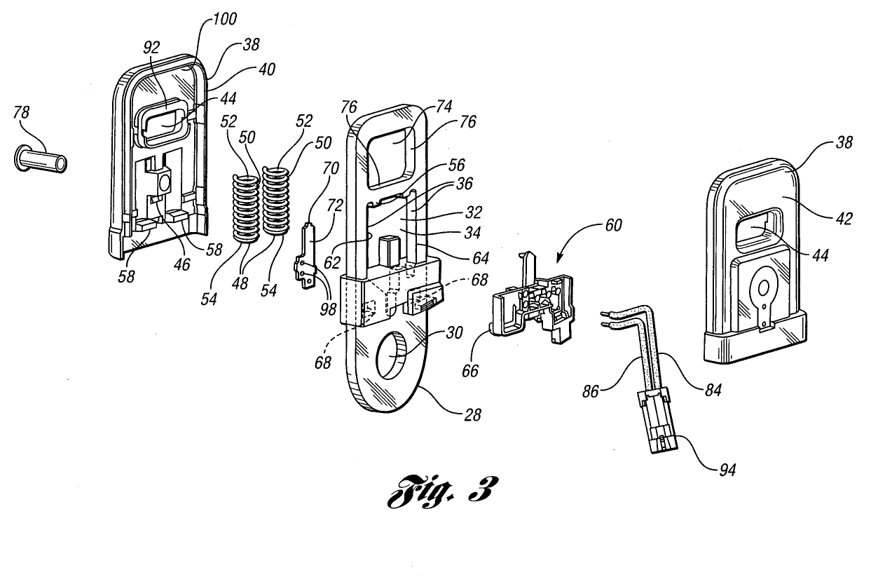

In this example, the magnets 46 are adjacent to the central space 34 and aligned with the HED in the rest condition. The HED is sensitive to the magnetic fields of the permanent magnets 46. As increasing tension is applied to the sensor assembly 10 by the seat belt 25, the housing 28 is pulled away from the anchor plate 28 in a direction A (FIG. 2), relative to its rest position, further compressing the compliant element 48 and moving the magnets 46 relative to the HED to provide the HED with a change in magnetic field. The HED converts the change in magnetic field to a voltage signal which is proportional to the force applied by the belt.

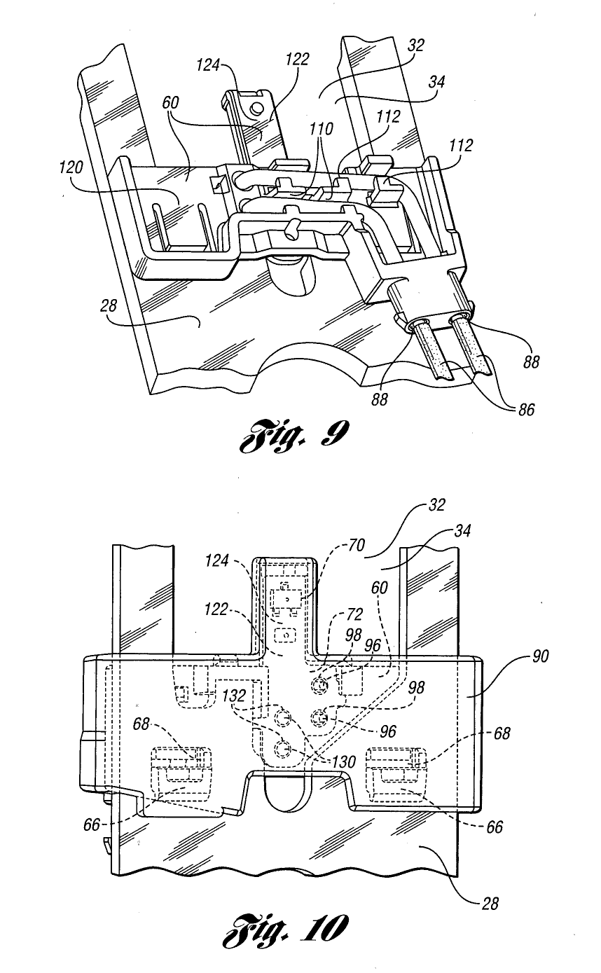

Referring now to FIGS. 1-10, in at least one embodiment, tension force from the seat belt webbing 25 causes the relative position between the housing 38 and the anchor plate 28 to change to a predetermined level of tension. Beyond the predetermined level of tension, the tension force on the seat belt webbing 25 is at least partially transferred to one of the first and second edge 36 and 76 of the anchor plate 28. In one example, the housing 38 has a flange 92 which pushes against the periphery of the seat belt loop 74, transferring force from the seat belt 25 to the second edge 76.

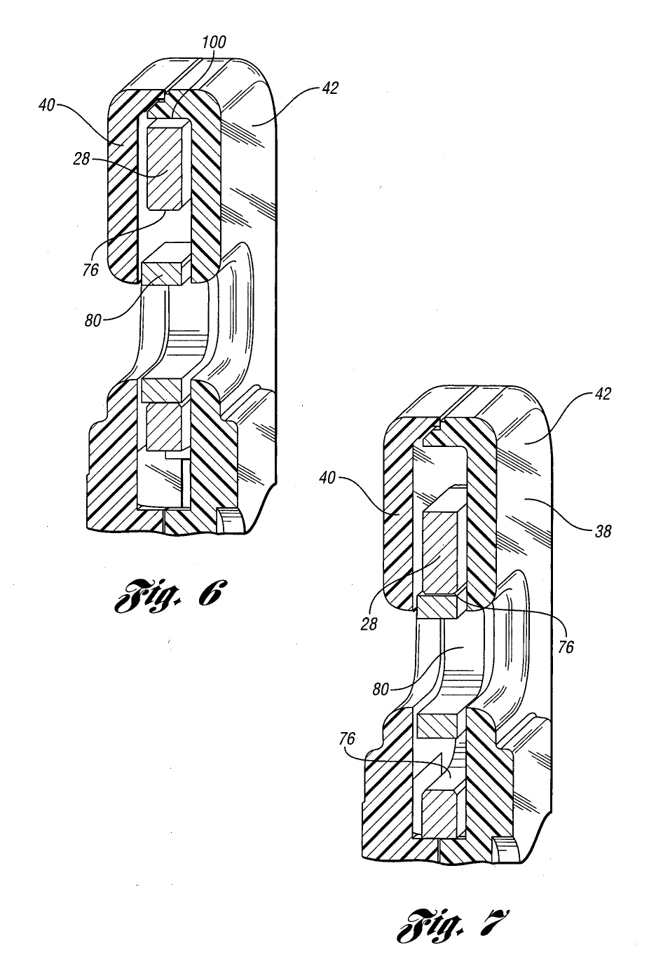

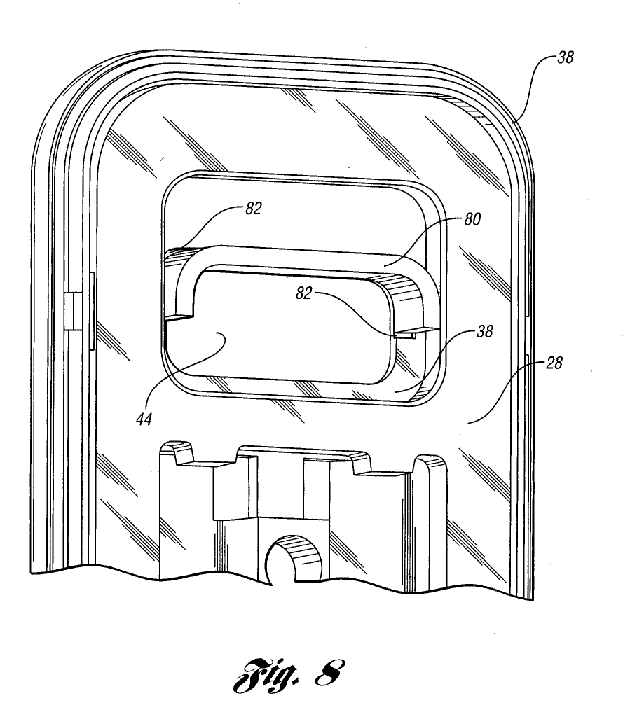

The sensor assembly 10 may further comprise a bushing element 80 disposed within the seat belt loop 74 and adjacent to the seat belt aperture 44. In this example, the housing 38 may not have a flange 92 adjacent to the seat belt aperture 44. The bushing element 80 is preferably at least partially enveloped by the housing 38. The bushing element 80 engages the seat belt 25 and is configured to at least partially transfer the tension force on the seat belt 25 to the second edge 76 of the anchor plate 28. In one example and as illustrated in FIGS. 6 and 7, the anchor plate 28 is biased towards the upper portion 100 of the housing 38 in the rest position (FIG. 6). When tension is applied by the seat belt 25, the housing 38 and the bushing element 80 move relative to the anchor plate 28 such that at a high tension condition (FIG. 7), the bushing element 80 pushes against the second edge 76 of the anchor plate 28.

The bushing element 80 may be a full bushing, a partial bushing or a spacer. For example, FIG. 8 illustrates the bushing element 80 that is a partial bushing disposed in a recessed feature 82 of the housing 38. The recessed feature 82 is preferably disposed about at least a portion of the seat belt aperture 44 of the housing 38. The recessed feature 82 engages the bushing element 80 such that when the tension force on the seat belt webbing 25 is transferred to the bushing element 80, the bushing element 80 and the housing 38 move in unison. Alternatively, the housing 38 and the bushing element 80 may be disengaged such that they move independently from each other in response to the tension force exerted by the seat belt 25.

A sensor assembly 10 may comprise a connector assembly 84. The connector assembly 84 has electrical conductors 86 electrically coupled to the second sensor element 70. In one example, the electrical conductors 86 have leads 96 that are soldered to the PCB 72 about solder points 98 and the PCB 72 is electrically coupled to the HED. The connector assembly 84 may further have a connector 94 which may either directly or indirectly interface with a controller for communicating the electrical signal.

In one embodiment, the strain relief element 60 has one or more channels 88 or tubular structures. Each channel 88 may have, for example, a single electrical conductor 86 disposed through the channel 88 such that the channel 88 securely positions the electrical conductor 86 on the strain relief element 60. Moreover, the strain relief element 60 may further have grooves 110 and/or hooks 112 for further securing and positioning the electrical conductors 86 proximate the solder points 98 so as to ensure that the soldering joints avoid excessive strain and stresses during seat belt tensioning or other forces. The channels 88 further ensure repeatable routing of the wires to enhance overall reliability.

The sensor assembly 10 may comprise a sealant 90 for providing environmental protection. The sealant is preferably a polymer and/or plastic based material, which is resistant to corrosion and may have relatively compliant physical properties allowing for differences in thermal expansion of the various components of the assembly 10. In at least one embodiment, the sealant 90 encapsulates the strain relief element 60, at least a portion of the electrical conductors 86 and at least a portion of the anchor plate 28 disposed adjacent to the positioning features 66.

The PCB 72 may be secured to the strain relief element 60, prior to the sealant 90 being applied. In this embodiment, it is unnecessary to provide location features for the encapsulation process which would otherwise penetrate the sealant 90, leaving potential corrosion paths within the sealant 90, which could adversely affect the HED and the electrical conductors 86. Thus, a more robust coating of the sealant 90 over the PCB 72 may be provided without the use of such location features. Moreover, with the electrical conductors 86 secured and positioned via the channels 88 prior to coating, the sealant is able to flow more readily around the wires, providing a continuous coating of the sealant around the electrical conductors 86, which improves sealing for corrosion protection from the environment.

As a person skilled in the art will readily appreciate, the above description is meant as an illustration of the implementation of the principles of this invention. This description is not intended to limit the scope or application of this invention in that the invention is susceptible to modification, variation and change without departing from the spirit of this invention, as defined in the following claims.

1. A sensor assembly for measuring tension loads applied by a seat belt for a motor vehicle, the sensor assembly comprising:
an anchor plate forming a first aperture to enable the anchor plate to be mounted to the motor vehicle, and forming a second aperture having a central space, the central space being defined by a first edge of the anchor plate;
a housing positioned to envelop at least a portion of the anchor plate, forming a seat belt aperture and having a first sensor element, the seat belt engaging the seat belt aperture;
a compliant element acting on the anchor plate and the housing causing the housing to move relative to the anchor plate in response to tension loads exerted by the seat belt when the anchor plate is mounted to the motor vehicle; and
a strain relief element disposed within the central space of the anchor plate between opposing sides of the first edge, the strain relief element having one or more positioning features to locate the strain relief element relative to the anchor plate, the strain relief element having a second sensor element interacting with the first sensor element to produce an electrical signal responsive to the relative position between the housing and the anchor plate.

2. The sensor assembly according to claim 1 wherein one of the first sensor element and the second sensor element is a permanent magnet and the other of the first sensor element and the second sensor element is a Hall Effect Device (HED).

3. The sensor assembly according to claim 1 wherein the anchor plate has a seat belt loop defined by a second edge of the anchor plate, the seat belt loop being for receiving the seat belt when the seat belt is placed through the seat belt aperture of the housing.

4. The sensor assembly according to claim 3 wherein the first and second edges of the anchor plate form the second aperture.

5. The sensor assembly according to claim 3 wherein the seat belt loop and the seat belt aperture are superimposed such that tension force on the seat belt webbing causes the relative position between the housing and the anchor plate to change to a predetermined level of tension, and beyond the predetermined level of tension, the tension force on the seat belt webbing is at least partially transferred to at least one of the first edge and the second edge of the anchor plate.

6. The sensor assembly according to claim 5 further comprising a bushing element disposed within the seat belt loop and adjacent to the seat belt aperture, the bushing element at least partially enveloped by the housing, wherein the seat belt engages the bushing element.

7. The sensor assembly according to claim 6 wherein the bushing element is configured to at least partially transfer the tension force on the seat belt webbing to the second edge of the anchor plate.

8. The sensor assembly according to claim 7 wherein the housing forms a recess feature disposed about at least a portion of the seat belt aperature, the recess feature engaging the bushing element such that the bushing element and the housing move together in response to tension loads exerted by the seat belt.

9. The sensor assembly according to claim 7 wherein the housing and the bushing element are disengaged such that the bushing element moves independently from the housing in response to tension loads exerted by the seat belt.

10. The sensor assembly according to claim 1 wherein the compliant element includes at least one compression coil spring.

11. The sensor assembly according to claim 1 wherein the compliant element is disposed within the central space of the second aperture, the compliant element having a first end engaging the anchor plate and a second end engaging the housing.

12. The sensor assembly according to claim 1 wherein the one or more positioning features includes a post formed by the strain relief element fitting within a bore formed by the anchor plate.

13. The sensor assembly according to claim 1 wherein the strain relief element further having one or more channels for carrying electrical conductors.

14. The sensor assembly according to claim 1 further comprising a sealant for providing environmental protection, the sealant encapsulating the strain relief element and at least a portion of the anchor plate disposed adjacent to the positioning features.

15. The sensor assembly according to claim 1 further comprising a connector assembly having electrical conductors electrically coupled to the second sensor element, the connector assembly being configured to interface with a controller for communicating the electrical signal.

16. A sensor assembly for measuring tension loads applied by a seat belt for a motor vehicle, the sensor assembly comprising:
an anchor plate having a first edge and a second edge and forming a first aperture to enable the anchor plate to be mounted to the motor vehicle, the anchor plate forming a second aperture having a central space defined by the first edge, the second edge of the anchor plate defining a seat belt loop;
a housing positioned to envelop at least a portion of the anchor plate, forming a seat belt aperture and having a first sensor element, the seat belt engaging the seat belt aperture;
a compliant element acting on the anchor plate and the housing causing the housing to move relative to the anchor plate in response to tension loads exerted by the seat belt when the anchor plate is mounted to the motor vehicle; and
a strain relief element disposed within the central space of the anchor plate between opposing sides of the first edge, the strain relief element having one or more positioning features to locate the strain relief element relative to the anchor plate, the strain relief element having a second sensor element interacting with the first sensor element to produce an electrical signal responsive to the relative position between the housing and the anchor plate, wherein the seat belt loop and the seat belt aperture are superimposed such that the seat belt loop receives the seat belt when the seat belt is placed through the seat belt aperture and tension force on the seat belt webbing causes the relative position between the housing and the anchor plate to change to a predetermined level of tension, and beyond the predetermined level of tension, the tension force on the seat belt webbing is at least partially transferred to at least one of the first edge and the second edge of the anchor plate.

17. The sensor assembly according to claim 16 further comprising a connector assembly having electrical conductors electrically coupled to the second sensor element, and wherein the strain relief element further having one or more channels that carry the electrical conductors.

18. The sensor assembly according to claim 17 further comprising a sealant for providing environmental protection, the sealant encapsulating the strain relief element, at least a portion of the electrical conductors and at least a portion of the anchor plate disposed adjacent to the positioning features.

19. The sensor assembly according to claim 17 wherein the strain relief element has one or more grooves for positioning the electrical conductors.

20. The sensor assembly according to claim 17 wherein the strain relief element has one or more hooks for holding the electrical conductors.

21. The sensor assembly according to claim 17 wherein the strain relief element has a first portion and a second portion, the first portion forming the positioning features and being positioned on the anchor plate, the second portion disposed within the central space and having an arm feature extending outwardly from the first portion and into the central space, the arm feature having the second sensor.

22. The sensor assembly according to claim 21 wherein the second sensor is a Hall Effect Device (HED) electrically coupled to a printed circuit board (PCB), the second portion having the PCB.

23. The sensor assembly according to claim 22 wherein second portion has at least one locator positive feature fitting within one of at least one locator opening formed by the PCB, the locator positive feature and the locator opening cooperating to position and secure the PCB to the second portion.

24. The sensor assembly according to claim 22 wherein each of the electrical conductors has a lead soldered to a corresponding solder point formed by the PCB, electrically coupling the electrical conductors to the PCB.

25. The sensor assembly according to claim 16 wherein the one or more positioning features includes a post formed by the strain relief element fitting within a bore formed by the anchor plate.
